(19) United States
(12) Patent Application Publication
(10) Pub. No.: US 2025/0351671 A1
(43) Pub. Date: Nov. 13, 2025

(54) DISPLAY DEVICE

(71) Applicant: Samsung Display Co., LTD., Yongin-si (KR)

(72) Inventors: Kyung Bae KIM, Yongin-si (KR); Kyeong Min PARK, Yongin-si (KR); Yong Hee LEE, Yongin-si (KR); Jin Joo HA, Yongin-si (KR)

(21) Appl. No.: 19/025,988

(22) Filed: Jan. 16, 2025

(30) Foreign Application Priority Data
May 10, 2024 (KR) 10-2024-0061849

(51) Int. Cl. H10K 59/121; H10K 59/131

(52) U.S. Cl. CPC H10K 59/1213; H10K 59/1216; H10K 59/131

(57) ABSTRACT

A display device includes: a first transistor; a light emitting element connected to the first transistor; and a first capacitor connected to a gate electrode of the first transistor, wherein the first capacitor includes: a first well region of a substrate; a source electrode and a drain electrode in the first well region; and a gate electrode in a channel region of the first well region, wherein the gate electrode of the first capacitor is connected to the gate electrode of the first transistor.

### CROSS-REFERENCE TO RELATED APPLICATION

The present application claims priority to and the benefit of Korean Patent Application No. 10-2024-0061849, filed on May 10, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

A head mounted display (HMD) is an image display device that may be worn on a user's head in the form of glasses or helmets to form a focus at a close distance in front of the user's eyes. The head mounted display may implement virtual reality (VR) or augmented reality (AR).

The head mounted display magnifies images displayed on a small display device by using a plurality of lenses, and displays the magnified images. Therefore, the display device applied to the head mounted display may desirably provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDOS is an image display device in which an organic light emitting diode (OLED) is located on a semiconductor wafer substrate on which a complementary metal oxide semiconductor (CMOS) is located.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device in which the thickness of a display panel may be relatively reduced.

Aspects of some embodiments of the present disclosure include a display device in which a thickness of a display panel can be relatively reduced.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of embodiments according to the present disclosure given below.

According to some embodiments of the present disclosure, a display device includes: a first transistor; a light emitting element connected to the first transistor; and a first capacitor connected to a gate electrode of the first transistor, wherein the first capacitor comprises a first well region of a substrate; a source electrode and a drain electrode in the first well region; and a gate electrode on a channel region of the first well region, and wherein the gate electrode of the first capacitor is connected to the gate electrode of the first transistor.

According to some embodiments, the first capacitor is further connected to the source electrode of the first transistor.

According to some embodiments, the source electrode and the drain electrode of the first capacitor are connected to the source electrode of the first transistor.

According to some embodiments, the first capacitor further includes a body electrode in the well region of the substrate.

According to some embodiments, the body electrode of the first capacitor is connected to the source electrode of the first transistor.

According to some embodiments, the display device further comprises a second capacitor connected between the gate electrode of the first transistor and the drain electrode of the first transistor.

According to some embodiments, the second capacitor comprises a second well region; a source electrode and a drain electrode in the second well region; and a gate electrode on a channel region of the second well region.

According to some embodiments, the gate electrode of the second capacitor is connected to the gate electrode of the first transistor.

According to some embodiments, the source electrode and the drain electrode of the second capacitor are connected to the drain electrode of the first transistor.

According to some embodiments, the second capacitor further comprises a body electrode in a well region of the substrate.

According to some embodiments, the body electrode of the second capacitor is connected to the drain electrode of the first transistor.

According to some embodiments, the first capacitor further comprises a gate insulating layer between the channel region of the first well region and the gate electrode of the first capacitor.

According to some embodiments, the first transistor comprises: a third well region on the substrate, a source electrode and a drain electrode in the third well region; a gate electrode on a channel region of the third well region; and a gate insulating layer between the channel region of the third well region and the gate electrode of the first transistor.

According to some embodiments, the gate insulating layer of the first capacitor has a smaller thickness than the gate insulating layer of the first transistor.

According to some embodiments, the second capacitor further comprises a gate insulating layer between the channel region of the second well region and the gate electrode of the second capacitor.

According to some embodiments, the gate insulating layer of the second capacitor has a smaller thickness than the gate insulating layer of the first transistor.

According to some embodiments, the source electrode and the drain electrode of the second capacitor are connected to the reference voltage line.

According to some embodiments, the second capacitor further comprises a body electrode in the well region of the substrate.

According to some embodiments, the body electrode of the second capacitor is connected to the reference voltage line.

According to some embodiments, the display device further comprises a driving voltage line connected to the source electrode of the first transistor; a second transistor connected between the gate electrode of the first transistor and a data line; and a scan line connected to the gate electrode of the second transistor.

According to some embodiments, the scan line, the driving voltage line, and the data line are on different layers on the substrate.

According to some embodiments, the driving voltage line is between the scan line and the data line.

In a display device according to some embodiments, a thickness of a display panel may be relatively reduced.

In a display device according to some embodiments, a capacitance may be relatively increased.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is an exploded perspective view showing a display device according to some embodiments;

FIG. 2 is a block diagram illustrating a display device according to some embodiments;

FIG. 3 is an equivalent circuit diagram of a first pixel according to some embodiments;

FIG. 4 is a circuit diagram showing aspects of the first capacitor and the second capacitor of FIG. 3 according to some embodiments;

FIG. 5 is a layout diagram illustrating an example of a display panel according to some embodiments;

FIGS. 6 and 7 are layout diagrams illustrating further details of the display area of FIG. 5 according to some embodiments;

FIG. 8 is a cross-sectional view illustrating further details of a display panel taken along the line X-X′ of FIG. 6 according to some embodiments;

FIG. 9 is a diagram showing a layout of a display panel according to some embodiments;

FIG. 10 is a cross-sectional view showing further details of a display panel taken along the line XI-XI′ of FIG. 9 according to some embodiments;

FIG. 11 is a cross-sectional view showing further details of a display panel taken along the line XI-XI′ of FIG. 9 according to some embodiments;

FIG. 12 is an equivalent circuit diagram of a first pixel according to some embodiments;

FIG. 13 is a circuit diagram showing an example of a first capacitor and a second capacitor of FIG. 12;

FIG. 14 is a perspective view illustrating a head mounted display according to some embodiments;

FIG. 15 is an exploded perspective view illustrating an example of the head mounted display of FIG. 14; and

FIG. 16 is a perspective view illustrating a head mounted display according to some embodiments.

### DETAILED DESCRIPTION

The present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

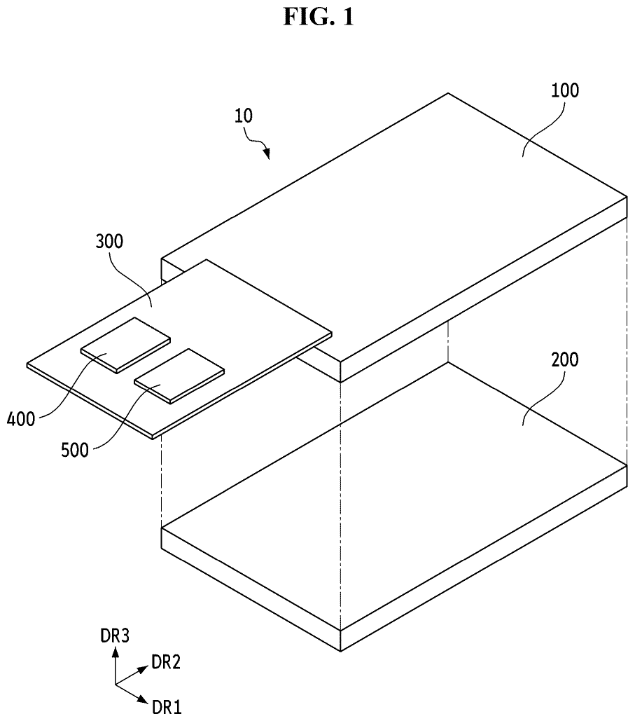

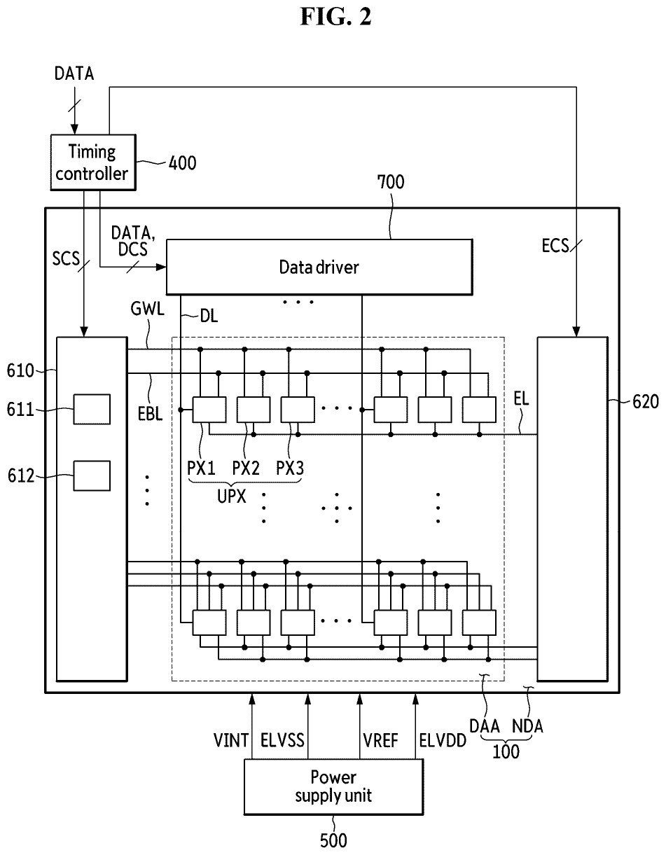

FIG. 1 is an exploded perspective view showing a display device according to some embodiments. FIG. 2 is a block diagram illustrating a display device according to some embodiments.

Referring to FIGS. 1 and 2, a display device 10 according to some embodiments is a device displaying moving images (e.g., video images) or still images (e.g., static images). The display device 10 according to some embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to some embodiments may be applied as a display unit of a television, a laptop, a monitor, a billboard, or an Internet-of-Things (IoT) terminal. Alternatively, the display device 10 according to some embodiments may be applied to a smart watch, a watch phone, a head mounted display (HMD) for implementing virtual reality and augmented reality, and the like.

The display device 10 according to some embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a curvature (e.g., a set or predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiments of the present disclosure are not limited thereto.

The display panel 100 includes a display area DAA displaying images and a non-display area NDA not displaying images as shown in FIG. 2.

The display area DAA includes a plurality of pixels PX, a plurality of scan lines GWL and EBL, a plurality of emission control lines EL, and a plurality of data lines DL.

The plurality of pixels PX may be arranged in a matrix form in the first direction DR1 and the second direction DR2. The plurality of scan lines GWL and EBL and the plurality of emission control lines EL may extend in the first direction DR1, while being arranged in the second direction DR2. The plurality of data lines DL may extend in the second direction DR2, while being arranged in the first direction DR1.

The plurality of scan lines GWL and EBL include a plurality of write scan lines GWL and a plurality of bias scan lines EBL.

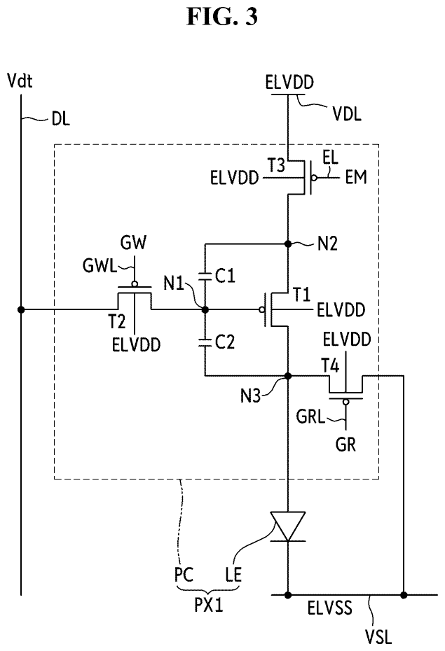

Each of a plurality of unit pixels UPX includes a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be located on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of bias scan lines EBL, any one of the plurality of emission control lines EL, and any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA includes a scan driver 610, an emission driver 620, and the data driver 700.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is located on the left side of the display area DAA and the emission driver 620 is located on the right side of the display area DAA, the embodiments of the present disclosure are not limited thereto. For example, the scan driver 610 and the emission driver 620 may be located on both the left side and the right side of the display area DAA.

The scan driver 610 may include a write scan signal output unit 611 and a bias scan signal output unit 612. Each of the write scan signal output unit 611 and the bias scan signal output unit 612 may receive a scan timing control signal SCS from the timing control circuit 400. The write scan signal output unit 611 may generate write scan signals according to the scan timing control signal SCS of the timing control circuit 400 and output them sequentially to the write scan lines GWL. The bias scan signal output unit 612 may generate bias scan signals according to the scan timing control signal SCS and output them sequentially to bias scan lines EBL.

The emission driver 620 may receive an emission timing control signal ECS from the timing control circuit 400. The emission driver 620 may generate emission control signals in response to the emission timing control signal ECS and sequentially output them to the emission control lines EL.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be located on one surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

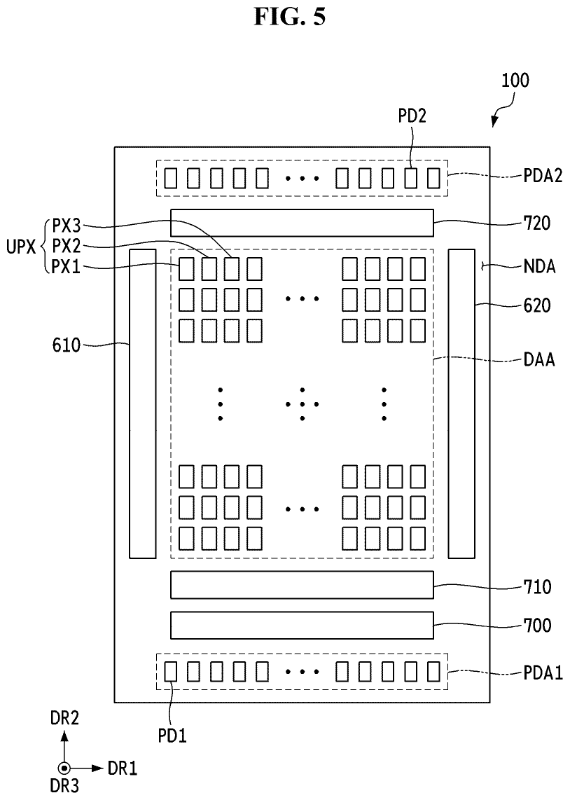

The circuit board 300 may be electrically connected to a plurality of first pads PD1 (see FIG. 5) of a first pad portion PDA1 (see FIG. 5) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. One end of the circuit board 300 may be an opposite end of the other end of the circuit board 300 connected to the plurality of first pads PD1 (see FIG. 5) of the first pad portion PDA1 (see FIG. 5) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a common voltage ELVSS, a driving voltage ELVDD, and an initialization voltage VINT and supply them to the display panel 100. The common voltage ELVSS, the driving voltage ELVDD, and the initialization voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the common voltage ELVSS, the driving voltage ELVDD, and the initialization voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be located between the data driver 700 and the first pad portion PDA1 (see FIG. 5).

FIG. 3 is an equivalent circuit diagram of a first pixel PX1 according to some embodiments. Although FIG. 3 illustrates various components in a pixel circuit of a pixel according to some embodiments, embodiments according to the present disclosure are not limited thereto, and according to various embodiments, the pixel circuit may include additional components or fewer components without departing from the spirit and scope of embodiments according to the present disclosure.

As shown in FIG. 3, a first pixel PX1 may be connected to the write scan line GWL, the bias scan line EBL, the emission control line EL, an initialization voltage line VIL, the data line DL, a driving voltage line VDL, and a common voltage line VSL. Here, the common voltage line VSL may be connected to the common electrode (e.g., cathode electrode) of a light emitting element ED.

The pixel PX may include a pixel circuit PC and the light emitting element ED.

The pixel circuit PC may include a first transistor T1, a second transistor T2, a third transistor T3, a fourth transistor T4, a first capacitor C1, a second capacitor C2, and a third capacitor C3.

The first transistor T1 (for example, a driving transistor) may include a gate electrode, a source electrode, a drain electrode, and a body electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×1(Vsg−Vth)²). Here, k is a proportional coefficient determined by the structure and physical characteristics of the first transistor T1, Vsg is a source-gate voltage of the first transistor T1, and Vth is a threshold voltage of the first transistor T1. The gate electrode of the first transistor T1 may be electrically connected to a first node N1, the source electrode thereof may be electrically connected to a second node N2, the drain electrode thereof may be electrically connected to a third node N3, and the body electrode thereof may be electrically connected to the driving voltage line VDL.

The light emitting element LE may emit light by receiving the driving current Isd. The emission amount or the luminance of the light emitting element ED may be proportional to the magnitude of the driving current Isd. The light emitting element ED may be an organic light emitting diode including a first electrode, a second electrode, and an organic light emitting layer located between the first electrode and the second electrode. According to some embodiments, the light emitting element ED may be an inorganic light emitting element including a first electrode, a second electrode, and an inorganic semiconductor located between the first electrode and the second electrode. According to some embodiments, the light emitting element ED may be a quantum dot light emitting element including a first electrode, a second electrode, and a quantum dot light emitting layer located between the first electrode and the second electrode. According to some embodiments, the light emitting element ED may be a micro light emitting diode. The first electrode of the light emitting element LE may be electrically connected to the third node N3. The second electrode of the light emitting element LE may be connected to the common voltage line VSL. The second electrode of the light emitting element LE may receive a common voltage (e.g., low potential voltage) from the common voltage line VSL.

The second transistor T2 may be turned on by the write scan signal GW of the write scan line GWL to electrically connect the data line DL with the first node N1. The gate electrode of the second transistor T2 may be electrically connected to the write scan line GWL, the source electrode thereof may be electrically connected to the data line DL, the drain electrode thereof may be electrically connected to the first node N1, and the body electrode thereof may be electrically connected to the driving voltage line VDL. The data line DL may transmit a data voltage Vdt.

The third transistor T3 may be turned on by an emission control signal EM of the emission control line EL to electrically connect the driving voltage line VDL with the second node N2. The gate electrode of the third transistor T3 may be electrically connected to the emission control line EL, the source electrode thereof may be electrically connected to the driving voltage line VDL, the drain electrode thereof may be electrically connected to the second node N2, and the body electrode thereof may be electrically connected to the driving voltage line VDL.

The fourth transistor T4 may be turned on by a reset scan signal GR of the reset scan line GRL to electrically connect the third node N3 and the common voltage line VSL. The gate electrode of the fourth transistor T4 may be electrically connected to the reset scan line GRL, the source electrode thereof may be electrically connected to the third node N3, the drain electrode thereof may be electrically connected to the common voltage line VSL, and the body electrode thereof may be electrically connected to the driving voltage line VDL.

The first capacitor C1 may be electrically connected between the first node N1 and the third node N3. For example, the first electrode of the first capacitor C1 may be electrically connected to the first node N1, and the second electrode of the first capacitor C1 may be electrically connected to the third node N3.

The second capacitor C2 may be electrically connected between the first node N1 and the second node N2. For example, the first electrode of the second capacitor C2 may be electrically connected to the first node N1, and the second electrode of the second capacitor C2 may be electrically connected to the second node N2.

The second capacitor C2 may have a capacitance larger than that of the first capacitor C1.

When the first transistor T1 and the third transistor T3 are turned on, a driving current may be supplied to the light emitting element LE, so that the light emitting element LE may emit light.

At least one of the aforementioned first to fourth transistors T1 to T4 may be a metal-oxide-semiconductor field effect transistor (MOSFET). For example, each of the first to fourth transistors T1 to T4 may be a P-type MOSFET. Meanwhile, according to some embodiments, each of the first to fourth transistors T1 to T4 may be an N-type MOSFET. According to some embodiments, some of the first to fourth transistors T1 to T4 may be P-type MOSFETs, and the other transistors may be N-type MOSFETS.

Although it is illustrated in FIG. 3 that the first pixel PX1 includes the four transistors T1 to T4 and the two capacitors C1 and C2, it should be noted that the equivalent circuit diagram of the first pixel PX1 is not limited to the example shown in FIG. 3. For example, the number of the transistors and the number of the capacitors of the first pixel PX1 are not limited to the example shown in FIG. 3.

According to some embodiments, the equivalent circuit diagram of a second pixel PX2 and the equivalent circuit diagram of a third pixel PX3 may be the same (or substantially the same) as the equivalent circuit diagram of the first pixel PX1 described in conjunction with FIG. 3. Thus, in the present disclosure, description of the equivalent circuit diagram of the second pixel PX2 and the equivalent circuit diagram of the third pixel PX3 will be omitted.

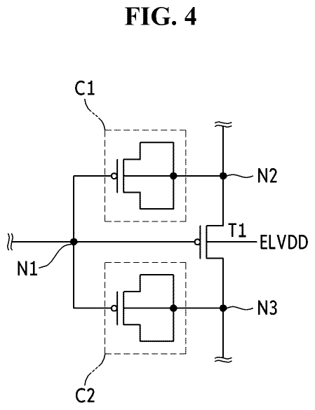

FIG. 4 is a circuit diagram showing aspects of the first capacitor C1 and the second capacitor C2 of FIG. 3 according to some embodiments.

According to some embodiments, at least one of the first capacitor C1 or the second capacitor C2 may include a metal oxide semiconductor (MOS).

For example, the first capacitor C1 may be implemented as a transistor connected between the first node N1 and the second node N2, as in the example shown in FIG. 4. In other words, the first capacitor C1 may be a metal oxide semiconductor (MOS) capacitor. According to some embodiments, the first capacitor C1 may be a P-type MOS capacitor including the gate electrode connected to the first node N1, the source electrode connected to the second node N2, the drain electrode connected to the second node N2, and the body electrode connected to the second node N2. However, embodiments of the present disclosure are not limited thereto, and the first capacitor C1 may be an N-type MOS capacitor.

The second capacitor C2 may be implemented as a transistor connected between the first node N1 and the third node N3, as in the example shown in FIG. 4. In other words, the second capacitor C2 may be a metal oxide semiconductor (MOS) capacitor. According to some embodiments, the second capacitor C2 may be a P-type MOS capacitor including the gate electrode connected to the first node N1, the source electrode connected to the third node N3, the drain electrode connected to the third node N3, and the body electrode connected to the third node N3. However, embodiments of the present disclosure are not limited thereto, and the second capacitor C2 may be an N-type MOS capacitor.

FIG. 5 is a layout diagram illustrating an example of a display panel according to some embodiments.

Referring to FIG. 5, the display area DAA of the display panel 100 according to some embodiments includes the plurality of pixels PX arranged in a matrix form. The non-display area NDA of the display panel 100 according to some embodiments includes the scan driver 610, the emission driver 620, the data driver 700, a first distribution circuit 710, a second distribution circuit 720, the first pad portion PDA1, and a second pad portion PDA2.

The scan driver 610 may be located on the first side of the display area DAA, and the emission driver 620 may be located on the second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, the embodiments of the present disclosure are not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on the third side of the display area DAA. For example, the first pad portion PDA1 may be located on one side of the display area DAA in the second direction DR2.

The first pad portion PDA1 may be located outside the data driver 700 in the second direction DR2. That is, the first pad portion PDA1 may be located closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA.

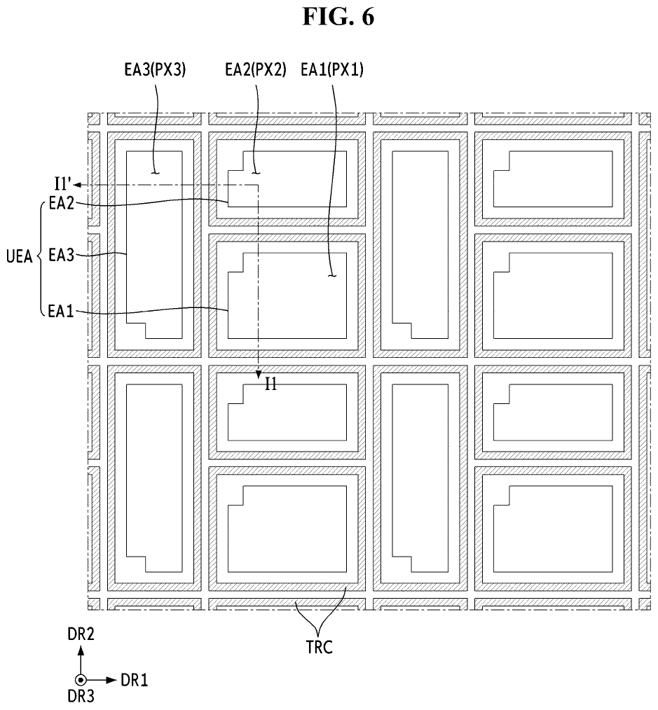

FIGS. 6 and 7 are layout diagrams illustrating embodiments of the display area of FIG. 5.

Referring to FIGS. 6 and 7, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 6 and 7, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in a plan view.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be the same (or substantially the same).

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in a plan view, a hexagonal shape formed of six straight lines as shown in FIGS. 6 and 7, but the embodiments of the present disclosure are not limited thereto. The first emission area EA1, the second emission area EA2, and the third emission area EA3 may have a polygonal shape other than a hexagon, a circular shape, an elliptical shape, or an atypical shape in a plan view.

As shown in FIG. 6, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 7, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is illustrated in FIGS. 6 and 7 that each of the plurality of pixels PX includes three emission areas EA1, EA2, and EA3, but the embodiments of the present disclosure are not limited thereto. That is, each of the plurality of pixels PX may include four emission areas.

In addition, the layout of the emission areas of the plurality of pixels PX is not limited to that illustrated in FIGS. 6 and 7. For example, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side as shown in FIG. 7.

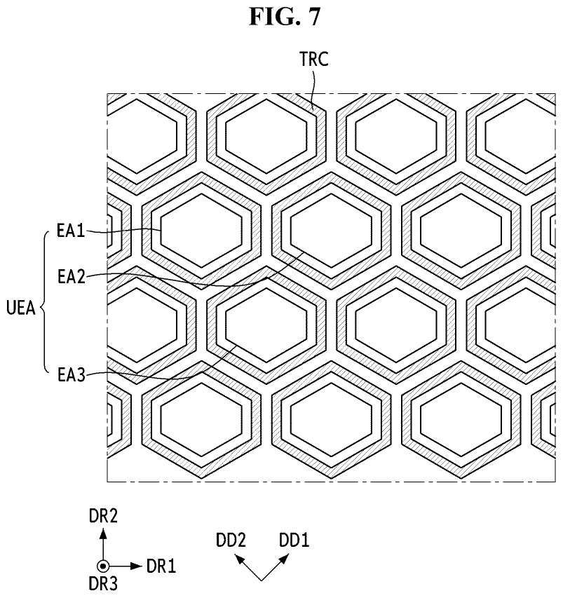

FIG. 8 is a cross-sectional view illustrating an example of a display panel taken along the line 11-11′ of FIG. 6.

Referring to FIG. 8, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR and a plurality of pixel capacitors PCP, a plurality of semiconductor insulating layers covering the plurality of pixel transistors PTR, and a plurality of contact terminals CTE electrically connected to the plurality of pixel transistors PTR, respectively. Here, the plurality of pixel transistors PTR may be the first to fourth transistors T1 to T4, respectively, described with reference to FIG. 3, and the plurality of pixel capacitors PCP may be the first and second capacitors C1 and C2, respectively, described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH located between the source region SA and the drain region DA.

A lower insulating layer BINS may be located between a gate electrode GE and the well region WA. A side insulating layer SINS may be located on the side surface of the gate electrode GE. The side insulating layer SINS may be located on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented or reduced.

A first semiconductor insulating layer SINS1 may be located on the semiconductor substrate SSUB. The first semiconductor insulating layer SINS1 may be formed of silicon carbonitride (SiCN) or a silicon oxide (SiOx)-based inorganic layer, but the embodiments of the present disclosure are not limited thereto.

A second semiconductor insulating layer SINS2 may be located on the first semiconductor insulating layer SINS1. The second semiconductor insulating layer SINS2 may be formed of a silicon oxide (SiOx)-based inorganic layer, but the embodiments of the present disclosure are not limited thereto.

The plurality of contact terminals CTE may be located on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be located on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the embodiments of the present disclosure are not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA6, and a plurality of insulating layers INS1 to INS6. In addition, the light emitting element backplane EBP includes a plurality of insulating layers INS1 to INS6 located between the first to fifth conductive layers ML1 to ML5.

The first to fifth conductive layers ML1 to ML5 serve to connect the plurality of contact terminals CTE exposed from the semiconductor backplane SBP to thereby implement the circuit of the first pixel PX1 shown in FIG. 3. For example, the first to fourth transistors T1 to T4 are merely formed on the semiconductor backplane SBP, and the connection of the first to fourth transistors T1 to T4 and the first and second capacitors C1 and C2 is accomplished through the first to fifth conductive layers ML1 to ML5.

A first insulating layer INS1 may be located on the semiconductor backplane SBP. Each of first vias VA1 may penetrate the first insulating layer INS1 to be connected to the contact terminal CTE exposed from the semiconductor backplane SBP. Each of first conductive layers ML1 may be located on the first insulating layer INS1 and may be connected to the first via VA1.

A second insulating layer INS2 may be located on the first insulating layer INS1 and the first conductive layers ML1. Each of second vias VA2 may penetrate the second insulating layer INS2 and be connected to the exposed first conductive layer ML1. Each of second conductive layers ML2 may be located on the second insulating layer INS2 and may be connected to the second via VA2.

A third insulating layer INS3 may be located on the second insulating layer INS2 and the second conductive layers ML2. Each of third vias VA3 may penetrate the third insulating layer INS3 and be connected to the exposed second conductive layer ML2. Each of third conductive layers ML3 may be located on the third insulating layer INS3 and may be connected to the third via VA3.

A fourth insulating layer INS4 may be located on the third insulating layer INS3 and the third conductive layers ML3. Each of fourth vias VA4 may penetrate the fourth insulating layer INS4 and be connected to the exposed third conductive layer ML3. Each of fourth conductive layers ML4 may be located on the fourth insulating layer INS4 and may be connected to the fourth via VA4.

A fifth insulating layer INS5 may be located on the fourth insulating layer INS4 and the fourth conductive layers ML4. Each of fifth vias VA5 may penetrate the fifth insulating layer INS5 and be connected to the exposed fourth conductive layer ML4. Each of fifth conductive layers ML5 may be located on the fifth insulating layer INS5 and may be connected to the fifth via VA5.

The first to fifth conductive layers ML1 to ML5 and the first to fifth vias VA1 to VA5 may be formed of the same material (or substantially the same material). The first to fifth conductive layers ML1 to ML5 and the first to fifth vias VA1 to VA5 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to fifth vias VA1 to VA5 may be made of the same material (or substantially the same material). First to fifth insulating layers INS1 to INS5 may be formed of a silicon oxide (SiOx)-based inorganic layer, but the embodiments of the present disclosure are not limited thereto.

The thickness of each of the fourth conductive layer ML4 and the fifth conductive layer ML5 may be larger than the thickness of the first conductive layer ML1, the thickness of the second conductive layer ML2, and the thickness of the third conductive layer ML3. The thickness of the fourth conductive layer ML4 and the fifth conductive layer ML5 may be larger than the thickness of the fourth via VA4 and the thickness of the fifth via VA5, respectively. The thickness of each of the fourth via VA4 and the fifth via VA5 may be larger than the thickness of the first via VA1, the thickness of the second via VA2, and the thickness of the third via VA3. The thickness of the fourth conductive layer ML4 and the fifth conductive layer ML5 may be the same (or substantially the same). For example, the thickness of each of the fourth conductive layer ML4 and the fifth conductive layer ML5 may be 9000 Å (or approximately 9000 Å). The thickness of each of the fourth via VA4 and the fifth via VA5 may be 6000 Å (or approximately 6000 Å).

A sixth insulating layer INS6 may be located on the fifth insulating layer INS5 and the fifth conductive layer ML5. The sixth insulating layer INS6 may be formed of a silicon oxide (SiOx)-based inorganic layer, but the embodiments of the present disclosure are not limited thereto.

Each of sixth vias VA6 may penetrate the sixth insulating layer INS6 and be connected to the exposed fifth conductive layer ML5. The sixth vias VA6 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the sixth via VA6 may be 16500 Å (or approximately 16500 Å).

The display element layer EML may be located on the light emitting element backplane EBP. The display element layer EML may include the light emitting elements LE each including a reflective electrode layer RL, seventh and eighth insulating layers INS7 and INS8, a seventh via VA7, a first electrode AND, a light emitting stack ES, and a second electrode CAT; a pixel defining layer PDL; and a plurality of trenches TRC.

The reflective electrode layer RL may be located on the sixth insulating layer INS6. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 8.

Each of the first reflective electrodes RL1 may be located on the sixth insulating layer INS6, and may be connected to the sixth via VA6. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be located on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be respectively located on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Because the second reflective electrode RL2 is an electrode that reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be 100 Å (or approximately 100 Å), and the thickness of the second reflective electrode RL2 may be 850 Å (or approximately 850 Å).

The seventh insulating layer INS7 may be located on the sixth insulating layer INS6. The seventh insulating layer INS7 may be located between the reflective electrode layers RL adjacent to each other in a horizontal direction. The seventh insulating layer INS7 may be located on the reflective electrode layer RL in the third pixel PX3. The seventh insulating layer INS7 may be formed of a silicon oxide (SiOx)-based inorganic layer, but the embodiments of the present disclosure are not limited thereto.

The eighth insulating layer INS8 may be located on the seventh insulating layer INS7 and the reflective electrode layer RL. The eighth insulating layer INS8 may be formed of a silicon oxide (SiOx)-based inorganic layer, but the embodiments of the present disclosure are not limited thereto. The seventh insulating layer INS7 and the eighth insulating layer INS8 may be an optical auxiliary layer through which light reflected by the reflective electrode layer RL passes, among light emitted from the light emitting elements LE.

In order to match the resonance distance of the light emitted from the light emitting elements LE in at least one of the first pixel PX1, the second pixel PX2, or the third pixel PX3, the seventh insulating layer INS7, or the eighth insulating layer INS8 may not be located under the first electrode AND of the first pixel PX1. The first electrode AND of the first pixel PX1 may be directly located on the reflective electrode layer RL. The eighth insulating layer INS8 may be located under the first electrode AND of the second pixel PX2. The seventh insulating layer INS7 and the eighth insulating layer INS8 may be located under the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the seventh insulating layer INS7 and the eighth insulating layer INS8 may be set in each of the first pixel PX1, the second pixel PX2, and the third pixel PX3. For example, it is illustrated in FIG. 6 that the distance between the first electrode AND and the reflective electrode layer RL in the third pixel PX3 is larger than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is larger than the distance between the first electrode AND and the reflective electrode layer RL in the first pixel PX1, but embodiments according to the present disclosure are not limited thereto.

In addition, although the seventh insulating layer INS7 and the eighth insulating layer INS8 are illustrated in the embodiments of the present disclosure, a ninth insulating layer located under the first electrode AND of the first pixel PX1 may be added. In this case, the eighth insulating layer INS8 and the ninth insulating layer may be located under the first electrode AND of the second pixel PX2, and the seventh insulating layer INS7, the eighth insulating layer INS8, and the ninth insulating layer may be located under the first electrode AND of the third pixel PX3.

Each of the seventh vias VA7 may penetrate the seventh insulating layer INS7 and/or the eighth insulating layer INS8 in the second pixel PX2 and the third pixel PX3 and may be connected to the reflective layer RL. The seventh vias VA7 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the seventh via VA7 in the second pixel PX2 may be smaller than the thickness of the seventh via VA7 in the third pixel PX3.

The first electrode AND of each of the light emitting elements LE may be located on the seventh insulating layer INS7 and connected to the seventh via VA7. The first electrode AND of each of the light emitting elements LE may be connected to the drain region DA or source region SA of the pixel transistor PTR through the seventh via VA7, the first to fourth reflective electrodes RL1 to RL4, the first to sixth vias VA1 to VA6, the first to fifth conductive layers ML1 to ML5, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining layer PDL may be located on a part of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining layer PDL may include first to third pixel defining layers PDL1, PDL2, and PDL3. The first pixel defining layer PDL1 may be located on the edge of the first electrode AND of each of the light emitting elements LE, the second pixel defining layer PDL2 may be located on the first pixel defining layer PDL1, and the third pixel defining layer PDL3 may be located on the second pixel defining layer PDL2. The first pixel defining layer PDL1, the second pixel defining layer PDL2, and the third pixel defining layer PDL3 may be formed of a silicon oxide (SiOx)-based inorganic layer, but the embodiments of the present disclosure are not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent or reduce instances of the first encapsulation inorganic layer TFE1 being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Furthermore, each of the plurality of trenches TRC may penetrate the eighth insulating layer INS8. The seventh insulating layer INS7 may be partially recessed at each of the plurality of trenches TRC.

At least one trench TRC may be located between adjacent pixels PX1, PX2, and PX3. Although FIG. 8 illustrates that two trenches TRC are located between adjacent pixels PX1, PX2, and PX3, the embodiments of the present disclosure are not limited thereto.

The light emitting stack ES may include a plurality of stack layers. FIG. 8 illustrates that the light emitting stack ES has a three-tandem structure including a first stack layer IL1, a second stack layer IL2, and a third stack layer IL3, but the embodiments of the present disclosure are not limited thereto. For example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be located on the first electrodes AND and the pixel defining layer PDL, and may be located on the bottom surface of each trench TRC. Due to the trench TRC, the first stack layer IL1 may be separated between adjacent pixels PX1, PX2, and PX3. The second stack layer IL2 may be located on the first stack layer IL1. Due to the trench TRC, the second stack layer IL2 may be separated between adjacent pixels PX1, PX2, and PX3. A cavity ESS or an empty space may be located between the first stack layer IL1 and the second stack layer IL2. The third stack layer IL3 may be located on the second stack layer IL2. The third stack layer IL3 is not cut off by the trench TRC and may be arranged to cover the second stack layer IL2 in each of the trenches TRC. That is, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In addition, in the two-tandem structure, each of the trenches TRC may be a structure for cutting off the charge generation layer located between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be located on the pixel defining layer PDL.

The number of the stack layers IL1, IL2, and IL3 that emit different lights is not limited to that shown in FIG. 8. For example, the light emitting stack ES may include two intermediate layers. In this case, one of the two intermediate layers may be the same (or substantially the same) as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be located between the two intermediate layers.

In addition, FIG. 8 illustrates that the first to third stack layers IL1, IL2, and IL3 are all located in the first emission area EA1, the second emission area EA2, and the third emission area EA3, but the embodiments of the present disclosure are not limited thereto. For example, the first stack layer IL1 may be located in the first emission area EA1, and may not be located in the second emission area EA2 and the third emission area EA3. Furthermore, the second stack layer IL2 may be located in the second emission area EA2 and may not be located in the first emission area EA1 and the third emission area EA3. Further, the third stack layer IL3 may be located in the third emission area EA3 and may not be located in the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be located on the display element layer EML. The encapsulation layer TFE may include at least one inorganic layer TFE1 and TFE2 to prevent or reduce instances of contaminants such as oxygen or moisture permeating into the display element layer EML. For example, the encapsulation layer TFE may include the first encapsulation inorganic layer TFE1, and a second encapsulation inorganic layer TFE2.

The first encapsulation inorganic layer TFE1 may be located on the second electrode CAT. The first encapsulation inorganic layer TFE1 may be formed as a multilayer in which one or more inorganic layers selected from silicon nitride (SINx), silicon oxy nitride (SiON), and silicon oxide (SiOx) are alternately stacked. The first encapsulation inorganic layer TFE1 may be formed by a chemical vapor deposition (CVD) process.

The second encapsulation inorganic layer TFE2 may be located on the first encapsulation inorganic layer TFE1. The second encapsulation inorganic layer TFE2 may be formed of titanium oxide (TiOx) or aluminum oxide (AlOx), but embodiments of the present disclosure are not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include a color filter layer CFL, a lens layer, a filling layer, a cover layer, and a polarizing plate.

The color filter layer CFL may include the first to third color filters CF1, CF2, and CF3. The first to third color filters CF1, CF2, and CF3 may be located on the organic layer APL.

The first color filter CF1 may overlap the first emission area EA1 of the first pixel PX1. The first color filter CF1 may transmit light of the first color, i.e., light of a blue wavelength band. The blue wavelength band may be in a range of 370 nanometers (nm) to 460 nm (or approximately 370 nm to 460 nm). Thus, the first color filter CF1 may transmit light of the first color among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be in a range of 480 nm to 560 nm (or approximately 480 nm to 560 nm). Thus, the second color filter CF2 may transmit light of the second color among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be in a range of 600 nm to 750 nm (or approximately 600 nm to 750 nm). Thus, the third color filter CF3 may transmit light of the third color among light emitted from the third emission area EA3.

A lens layer LSL may include a plurality of lenses LNS. The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

A filling layer FIL may be located on the lens layer LSL. For example, the filling layer FIL may be located on the plurality of lenses LNS. The filling layer FIL may have a refractive index (e.g., a set or predetermined refractive index) such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for preventing or reducing visibility degradation caused by reflection of external light. The polarizing plate POL may include a linear polarizing plate and a phase retardation film. For example, the phase retardation film may be a λ/4 plate (quarter-wave plate), but the embodiments of the present disclosure are not limited thereto. However, when visibility degradation caused by reflection of external light is sufficiently overcome by the first to third color filters CF1, CF2, and CF3, the polarizing plate POL may be omitted.

According to some embodiments, the first conductive layer ML1 described above may include a scan line. For example, one of the first conductive layer ML1 may be a scan line. In this case, the scan line may be located on the first insulating layer INS1. Here, the scan line may include at least one of the write scan line GWL or the reset scan line GRL described above.

According to some embodiments, the first conductive layer ML1 described above may include an emission control line EL. For example, one of the first conductive layer ML1 may be an emission control line EL. In this case, the emission control line EL may be located on the first insulating layer INS1.

According to some embodiments, the second conductive layer ML2 described above may include a driving voltage line VDL. For example, one of the second conductive layer ML2 may be a driving voltage line VDL. In this case, the driving voltage line VDL may be located between the first conductive layer ML1 and the third conductive layer ML3.

According to some embodiments, the third conductive layer ML3 described above may include a data line DL. For example, one of the third conductive layer ML3 may be a data line DL. In this case, the data line DL may be located between the second conductive layer ML2 and the fourth conductive layer ML4.

As described above, the driving voltage line VDL may be located between the scan line and the data line DL. At this time, the driving voltage line VDL and the scan line may overlap in the third direction DR3, and the driving voltage line VDL and the data line DL may overlap in the third direction DR3. Accordingly, the driving voltage line VDL may function as a shielding layer that can block coupling between the scan line and the data line DL. Therefore, a kickback phenomenon in which the data voltage of the data line DL fluctuates due to the influence of the scan signal of the scan line may be prevented or reduced. In addition, because the driving voltage line VDL functions as a shielding layer, the data line DL is not required to have a large area. Accordingly, the overlapping area between the driving voltage line VDL and the data line DL may be reduced and the capacitance of the data line may be reduced. Thus, power consumption may be reduced.

According to some embodiments, the pixel capacitor PCP may be an MOS capacitor as described above. The pixel capacitor PCP may have the same configuration as the pixel transistor PTR described above. According to some embodiments, the pixel capacitor PCP is formed in the form of a transistor (e.g., the form of a MOS transistor) on the semiconductor substrate SSUB rather than on the light emitting element backplane EBP. For example, according to some embodiments, a circuit may be configured with only four transistors T1 to T4 as shown in FIG. 3 instead of six transistors, and the first capacitor C1 and the second capacitor C2 may be formed respectively in the form of a MOS transistor in an area where the removed two transistors occupied. Accordingly, the thickness of the display panel 100 may be reduced.

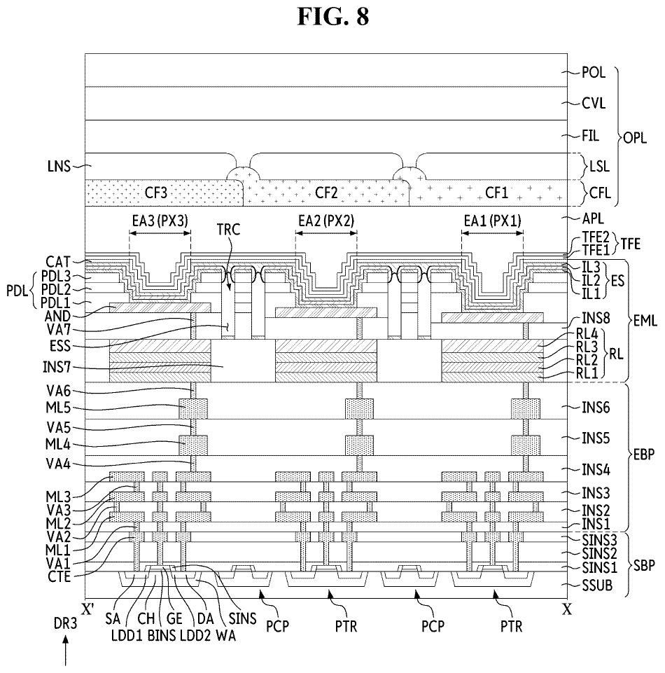

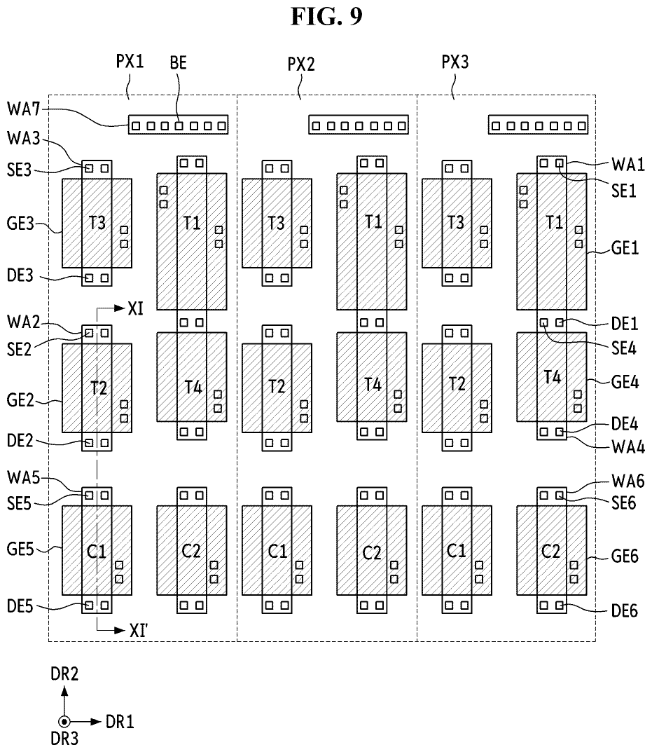

The pixel capacitor PCP will be described in detail with reference to FIGS. 9 and 10.

FIG. 9 is a diagram showing a layout of a display panel 100 according to some embodiments. For example, FIG. 9 may be a diagram showing a layout in respect to some embodiments of the display area DAA of FIG. 5. FIG. 10 is a cross-sectional view showing an example of a display panel 100 taken along the line XI-XI′ of FIG. 9.

As shown in FIG. 9, a plurality of pixels may be located in the display area DAA of the display panel 100. For example, a first pixel PX1, a second pixel PX2, and a third pixel PX3 are illustrated in FIG. 9.

Each of the pixels PX1, PX2, and PX3 may include a first transistor T1, a second transistor T2, a third transistor T3, a fourth transistor T4, a first capacitor C1 (e.g., an MOS capacitor), and a second capacitor C2 (e.g., an MOS capacitor).

Because the components of the pixels PX1, PX2, and PX3 are the same (or substantially the same), the first pixel PX1 will be representatively described.

The third transistor T3, the second transistor T2, and the first capacitor C1 of the first pixel PX1 may be arranged in a line along the second direction DR2 in the first column of the first pixel PX1. The body electrode BE, the first transistor T1, the fourth transistor T4, and the second capacitor C2 of the first pixel PX1 may be arranged in a line along the second direction DR2 in the second column of the first pixel PX1. The body electrode BE may be located in the first row of the first pixel PX1, the third transistor T3 and the first transistor T1 may be located adjacent to each other in the first direction DR1 in the second row of the first pixel PX1, the second transistor T2 and the fourth transistor T4 may be located adjacent to each other in the first direction DR1 in the third row of the first pixel PX1, and the first capacitor C1 and the second capacitor C2 may be located adjacent to each other in the first direction DR1 in the fourth row of the first pixel PX1. In the first pixel PX1, the second transistor T2 may be located between the third transistor T3 and the first capacitor C1, the first transistor T1 may be located between the body electrode BE and the fourth transistor T4, and the fourth transistor T4 may be located between the first transistor T1 and the second capacitor C2.

The first transistor T1 may include a first gate electrode GE1, a first source electrode SE1, a first drain electrode DE1, a first gate insulating layer, a first sidewall, a first well region WA1, a first channel region, and first low-concentration impurity regions. A first gate insulating layer Gox1 may be located between the first channel region and the first gate electrode GE1. The first channel region may be located between the first source electrode SE1 and the first drain electrode DE1 in the first well region WA1. The first low-concentration impurity regions may each be located between the first source electrode SE1 and the first channel region, and between the first drain electrode DE1 and the first channel region. The first sidewall may be located on side surfaces of the first gate insulating layer and the first gate electrode GE1 so to overlap the first low-concentration impurity region. At this time, in a plan view, the first sidewall may be located on the first low-concentration impurity region to surround the side surface of the first gate insulating layer and the side surface of the first gate electrode GE1.

As illustrated in FIGS. 9 and 10, the second transistor T2 may include a second gate electrode GE2, a second source electrode SE2, a second drain electrode DE2, a second gate insulating layer Gox2, a second sidewall, a second well region WA2, a second channel region, and second low-concentration impurity regions. The second gate insulating layer Gox2 may be located between the second channel region and the second gate electrode GE2. The second channel region may be located between the second source electrode SE2 and the second drain electrode DE2 in the second well region WA2. The second low-concentration impurity regions may each be located between the second source electrode SE2 and the second channel region, and between the second drain electrode DE2 and the second channel region. The second sidewall may be located on side surfaces of the second gate insulating layer Gox2 and the second gate electrode GE2 so to overlap the second low-concentration impurity region. At this time, in a plan view, the second sidewall may be located on the second low-concentration impurity region to surround the side surface of the second gate insulating layer Gox2 and the side surface of the second gate electrode GE2.

The third transistor T3 may include a third gate electrode GE3, a third source electrode SE3, a third drain electrode DE3, a third gate insulating layer, a third sidewall, a third well region WA3, a third channel region, and third low-concentration impurity regions. The third gate insulating layer may be located between the third channel region and the third gate electrode GE3. The third channel region may be located between the third source electrode SE3 and the third drain electrode DE3 in the third well region WA3. The third low-concentration impurity regions may each be located between the third source electrode SE3 and the third channel region, and between the third drain electrode DE3 and the third channel region. The third sidewall may be located on side surfaces of the third gate insulating layer and the third gate electrode GE3 so to overlap the third low-concentration impurity region. At this time, in a plan view, the third sidewall may be located on the third low-concentration impurity region to surround the side surface of the third gate insulating layer and the side surface of the third gate electrode GE3.

The fourth transistor T4 may include a fourth gate electrode GE4, a fourth source electrode SE4, a fourth drain electrode DE4, a fourth gate insulating layer, a fourth sidewall, a fourth well region WA4, a fourth channel region, and fourth low-concentration impurity regions. The fourth gate insulating layer may be located between the fourth channel region and the fourth gate electrode GE4. The fourth channel region may be located between the fourth source electrode SE4 and the fourth drain electrode DE4 in the fourth well region WA4. The fourth low-concentration impurity regions may each be located between the fourth source electrode SE4 and the fourth channel region, and between the fourth drain electrode DE4 and the fourth channel region. The fourth sidewall may be located on side surfaces of the fourth gate insulating layer and the fourth gate electrode GE4 so to overlap the fourth low-concentration impurity region. At this time, in a plan view, the fourth sidewall may be located on the fourth low-concentration impurity region to surround the side surface of the fourth gate insulating layer and the side surface of the fourth gate electrode GE4. Meanwhile, the fourth well region WA4 and the first well region WA1 may be integrally formed.

As illustrated in FIGS. 9 and 10, the first capacitor C1 may include a fifth gate electrode GE5, a fifth source electrode SE5, a fifth drain electrode DE5, a fifth gate insulating layer Gox5, a fifth sidewall SW5, a fifth well region WA5, a fifth channel region CH5, and fifth low-concentration impurity regions LDD5. The fifth gate insulating layer Gox5 may be located between the fifth channel region CH5 and the fifth gate electrode GE5. The fifth channel region CH5 may be located between the fifth source electrode SE5 and the fifth drain electrode DE5 in the fifth well region WA5. The fifth low-concentration impurity regions LDD5 may each be located between the fifth source electrode SE5 and the fifth channel region CH5, and between the fifth drain electrode DE5 and the fifth channel region CH5. The fifth sidewall SW5 may be located on the side surfaces of the fifth gate insulating layer Gox5 and the fifth gate electrode GE5 so to overlap the fifth low-concentration impurity region LDD5. At this time, in a plan view, the fifth sidewall SW5 may be located on the fifth low-concentration impurity region LDD5 to surround the side surface of the fifth gate insulating layer Gox5 and the side surface of the fifth gate electrode GE5.

The second capacitor C2 may include a sixth gate electrode GE6, a sixth source electrode SE6, a sixth drain electrode DE6, a sixth gate insulating layer, a sixth sidewall, a sixth well region WA6, a sixth channel region, and sixth low-concentration impurity regions. The sixth gate insulating layer may be located between the sixth channel region and the sixth gate electrode GE6. The sixth channel region may be located between the sixth source electrode SE6 and the sixth drain electrode DE6 in the sixth well region WA6. The sixth low-concentration impurity regions may each be located between the sixth source electrode SE6 and the sixth channel region, and between the sixth drain electrode DE6 and the sixth channel region. The sixth sidewall may be located on the side surfaces of the sixth gate insulating layer and the sixth gate electrode GE6 so to overlap the sixth low-concentration impurity region. At this time, in a plan view, the sixth sidewall may be located on the sixth low-concentration impurity region to surround the side surface of the sixth gate insulating layer and the side surface of the sixth gate electrode GE6.

Each body electrode BE of the first to fourth transistors T1 to T4, the first capacitor C1, and the second capacitor C2 may be located in the sixth well region WA6 on the semiconductor substrate SSUB. In other words, the body electrode BE may be located in a separate well region WA6 in the same manner as the source electrode or drain electrode of each transistor T1 to T4 described above.

The first transistor T1, the third transistor T3, and the fourth transistor T4 may each have the same cross-sectional structure as the second transistor T2 shown in FIG. 10.

The second capacitor C2 may have the same cross-section as the first capacitor C1 shown in FIG. 10.

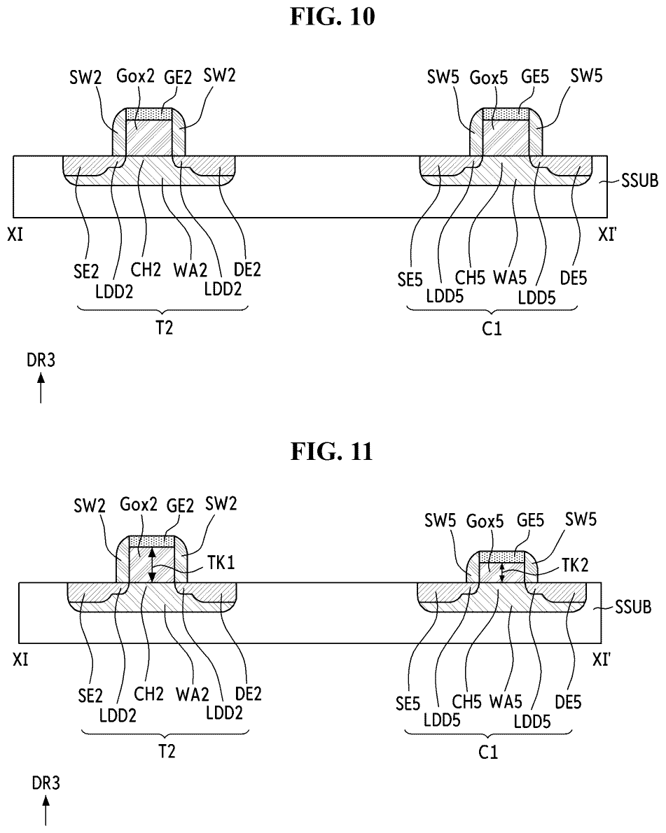

According to some embodiments, the thickness of each of the gate insulating layer of at least two transistors may be different. This will be described with reference to FIG. 11.

FIG. 11 is a cross-sectional view showing another example of a display panel taken along the line XI-XI′ of FIG. 9. The display panel of FIG. 11 is different from the display panel of FIG. 10 in the thickness of the gate insulating layer, and the difference will be mainly described as below.

According to some embodiments, a gate insulating layer provided in at least one capacitor may have a different thickness than the gate insulating layer provided in at least one transistor. For example, as shown in FIG. 11, a thickness TK2 of the fifth gate insulating layer Gox5 provided in the first capacitor C1 may be smaller than a thickness TK1 of the second gate insulating layer Gox2 provided in the second transistor T2. Accordingly, the capacity of the first capacitor C1 may increase. For example, because the first capacitor C1 of FIG. 11 has the fifth gate insulating layer Gox5 with a relatively small thickness, the distance between the fifth gate electrode GE5 and the fifth channel region CH5 (or the distance between the fifth gate electrode GE5 and the semiconductor substrate SSUB) may become short and the capacity of the first capacitor C1 may increase. Meanwhile, like the first capacitor C1 shown in FIG. 11, the sixth gate insulating layer of the second capacitor C2 may have a smaller thickness than the gate insulating layer provided in at least one transistor.

The second capacitor C2 may have the same cross-section as the first capacitor C1 shown in FIG. 11.

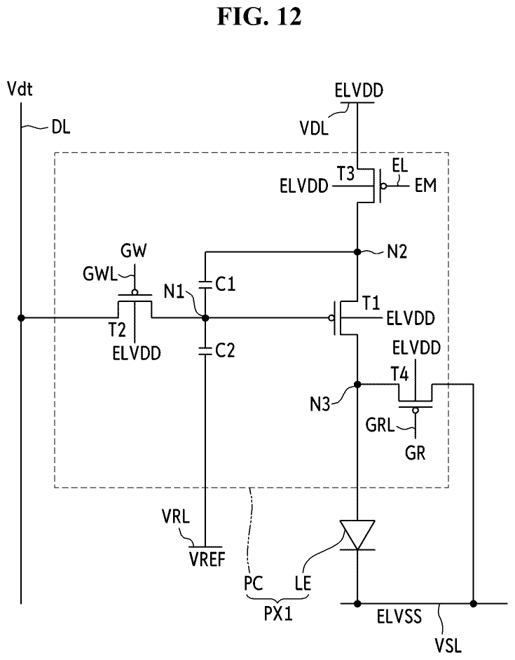

FIG. 12 is an equivalent circuit diagram of a first pixel PX1 according to some embodiments. Although FIG. 12 illustrates various components in a pixel circuit of a pixel according to some embodiments, embodiments according to the present disclosure are not limited thereto, and according to various embodiments, the pixel circuit may include additional components or fewer components without departing from the spirit and scope of embodiments according to the present disclosure.

The equivalent circuit diagram of FIG. 12 is different from the equivalent circuit diagram of FIG. 3 described above in a connection relationship of the second capacitor C2, and the difference will be mainly described below.

As shown in FIG. 12, the second capacitor C2 may be connected between the first node N1 and a reference voltage line VRL. For example, a first electrode of the second capacitor C2 may be connected to the first node N1, and a second electrode of the second capacitor C2 may be connected to the reference voltage line VRL.

According to some embodiments, the equivalent circuit diagram of the second pixel PX2 and the equivalent circuit diagram of the third pixel PX3 may be the same (or substantially the same) as the equivalent circuit diagram of the first pixel PX1 described with reference to FIG. 12. Therefore, descriptions of the equivalent circuit diagram of the second pixel PX2 and the equivalent circuit diagram of the third pixel PX3 are omitted in the present specification.

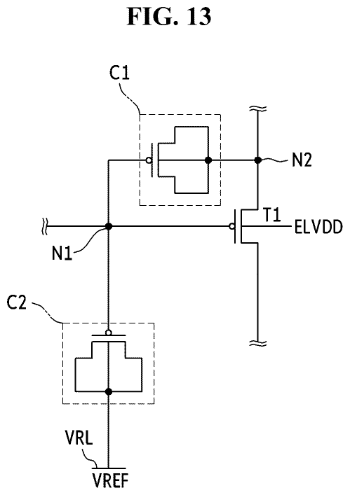

FIG. 13 is a circuit diagram showing an example of a first capacitor C1 and a second capacitor C2 of FIG. 12.

According to some embodiments, at least one of the first capacitor C1 or the second capacitor C2 may include a metal oxide semiconductor (MOS).

For example, as shown in FIG. 13, the first capacitor C1 may be implemented as a transistor connected between the first node N1 and the second node N2. In other words, the first capacitor C1 may be an MOS capacitor. According to some embodiments, the first capacitor C1 may be a P-type MOS capacitor including a gate electrode connected to the first node N1, a source electrode connected to the second node N2, a drain electrode connected to the second node N2, and a body electrode connected to the second node N2. For example, the first capacitor C1 of FIG. 13 may have the same structure as the first capacitor C1 as shown in FIG. 10 or the first capacitor C1 as shown in FIG. 11 described above. However, embodiments according to the present disclosure are not limited thereto, and the first capacitor C1 may be an N-type MOS capacitor.

As shown in FIG. 13, the second capacitor C2 may be implemented as a transistor connected between the first node N1 and the reference voltage line VRL. In other words, the second capacitor C2 may be an MOS capacitor. According to some embodiments, the second capacitor C2 may be a P-type MOS capacitor including a gate electrode connected to the first node N1, a source electrode connected to the reference voltage line VRL, a drain electrode connected between the reference voltage lines VRL, and a body electrode connected between the reference voltage lines VRL. For example, the second capacitor C2 of FIG. 13 may have the same structure as the first capacitor C1 as shown in FIG. 10 or the first capacitor C1 as shown in FIG. 11 described above. However, embodiments according to the present disclosure are not limited thereto, and the second capacitor C2 may be an N-type MOS capacitor.

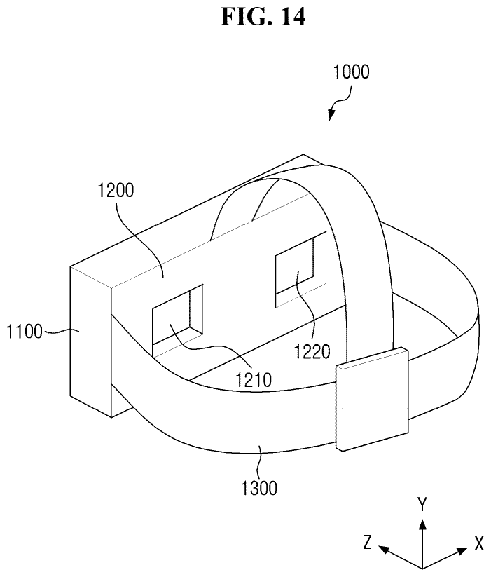

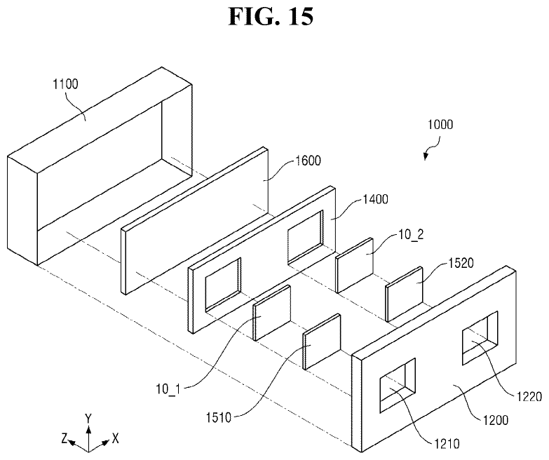

FIG. 14 is a perspective view illustrating a head mounted display according to some embodiments. FIG. 15 is an exploded perspective view illustrating an example of the head mounted display of FIG. 24.

Referring to FIGS. 14 and 15, a head mounted display 1000 according to some embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 displays images to the user's left eye, and the second display device 10_2 displays images to the user's right eye. Because each of the first display device 10_1 and the second display device 10_2 is the same (or substantially the same) as the display device 10 described in conjunction with FIGS. 1 to 13, a description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 14 and 15 illustrate that the first eyepiece 1210 and the second eyepiece 1220 are arranged separately, but the embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

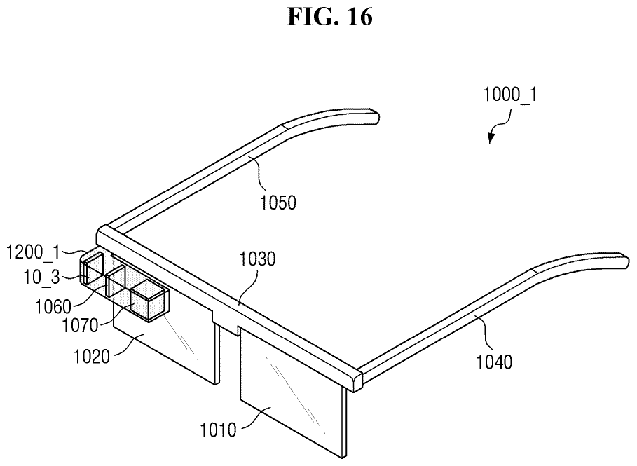

The head mounted band 1300 serves to secure the display device housing 1100 to the user's head such that the first eyepiece 1210 and the second eyepiece 1220 of the housing cover 1200 remain arranged on the user's left and right eyes, respectively. When the display device housing 1200 is implemented to be lightweight and compact, the head mounted display 1000 may be provided with, as shown in FIG. 16, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 16 is a perspective view illustrating a head mounted display according to some embodiments.

Referring to FIG. 16, a head mounted display 1000_1 according to some embodiments may be an eyeglasses-type display device in which a display device housing 1200_1 is implemented in a lightweight and compact manner. The head mounted display 1000_1 according to some embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 16 illustrates that the display device housing 1200_1 is located at the right end of the support frame 1030, but the embodiments of the present disclosure are not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

It will be able to be understood by one of ordinary skill in the art to which the present disclosure belongs that the present disclosure may be implemented in other specific forms without changing the technical spirit or essential features of the present disclosure. Therefore, it is to be understood that the disclosed embodiments described above are illustrative rather than being restrictive in all aspects. It is to be understood that the scope of embodiments according to the present disclosure are defined by the appended claims, and their equivalents, rather than the detailed description described above and all modifications and alterations derived from the claims and their equivalents fall within the scope of embodiments according to the present disclosure.

What is claimed is:

1. A display device comprising:
a first transistor;
a light emitting element connected to the first transistor; and
a first capacitor connected to a gate electrode of the first transistor,
wherein the first capacitor comprises:
a first well region of a substrate;
a source electrode and a drain electrode in the first well region; and
a gate electrode in a channel region of the first well region,
wherein the gate electrode of the first capacitor is connected to the gate electrode of the first transistor.

2. The display device of claim 1,
wherein the first capacitor is further connected to the source electrode of the first transistor.

3. The display device of claim 2,
wherein the source electrode and the drain electrode of the first capacitor are connected to the source electrode of the first transistor.

4. The display device of claim 3,
wherein the first capacitor further comprises a body electrode in the first well region of the substrate.

5. The display device of claim 4,
wherein the body electrode of the first capacitor is connected to the source electrode of the first transistor.

6. The display device of claim 1,
further comprising a second capacitor connected between the gate electrode of the first transistor and the drain electrode of the first transistor.

7. The display device of claim 6,
wherein the second capacitor comprises:
a second well region of the substrate;
a source electrode and a drain electrode in the second well region; and
a gate electrode in a channel region of the second well region.

8. The display device of claim 7,
wherein the gate electrode of the second capacitor is connected to the gate electrode of the first transistor.

9. The display device of claim 7,
wherein the source electrode and the drain electrode of the second capacitor are connected to the drain electrode of the first transistor.

10. The display device of claim 9,
wherein the second capacitor further comprises a body electrode in the second well region of the substrate.

11. The display device of claim 10,
wherein the body electrode of the second capacitor is connected to the drain electrode of the first transistor.

12. The display device of claim 1,
wherein the first capacitor further comprises a gate insulating layer between the channel region of the first well region and the gate electrode of the first capacitor.

13. The display device of claim 12,
wherein the first transistor comprises:
a third well region of the substrate;
a source electrode and a drain electrode in the third well region;
a gate electrode on a channel region of the third well region; and
a gate insulating layer between the channel region of the third well region and the gate electrode of the first transistor.

14. The display device of claim 13,
wherein the gate insulating layer of the first capacitor has a smaller thickness than the gate insulating layer of the first transistor.

15. The display device of claim 7,
wherein the second capacitor further comprises a gate insulating layer between the channel region of the second well region and the gate electrode of the second capacitor.

16. The display device of claim 15,
wherein the gate insulating layer of the second capacitor has a smaller thickness than the gate insulating layer of the first transistor.

17. The display device of claim 1,
further comprising a second capacitor between the gate electrode of the first transistor and a reference voltage line.

18. The display device of claim 17,
wherein the second capacitor comprises:
a second well region of the substrate;
a source electrode and a drain electrode in the second well region; and
a gate electrode in a channel region of the second well region.

19. The display device of claim 18,
wherein the gate electrode of the second capacitor is connected to the gate electrode of the first transistor.

20. The display device of claim 18,
wherein the source electrode and the drain electrode of the second capacitor are connected to the reference voltage line.

21. The display device of claim 20,
wherein the second capacitor further comprises a body electrode in the second well region of the substrate.

22. The display device of claim 21,
wherein the body electrode of the second capacitor is connected to the reference voltage line.

23. The display device of claim 1, further comprising:
a driving voltage line connected to the source electrode of the first transistor;
a second transistor connected between the gate electrode of the first transistor and a data line; and
a scan line connected to a gate electrode of the second transistor.

24. The display device of claim 23,
wherein the scan line, the driving voltage line, and the data line are on different layers on the substrate.

25. The display device of claim 24,
wherein the driving voltage line is between the scan line and the data line.

26. An electronic device comprising:
a display device comprising a screen,
wherein the display device comprises
a first transistor;
a light emitting element connected to the first transistor; and
a first capacitor connected to a gate electrode of the first transistor,
wherein the first capacitor comprises:
a first well region of a substrate;
a source electrode and a drain electrode in the first well region; and
a gate electrode in a channel region of the first well region,
wherein the gate electrode of the first capacitor is connected to the gate electrode of the first transistor.
